(19) United States
(12) Patent Application Publication
(10) Pub. No.: US 2008/0087933 A1
(43) Pub. Date: Apr. 17, 2008

(54) Semiconductor memory device and method of manufacturing the same

(76) Inventors: Eun-Kuk Chung, Seoul (KR); Joon Kim, Seoul (KR); Jin-Hong Kim, Suwon-si (KR); Suk-Chul Bang, Yongin-si (KR); Jong-Seon Ahn, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/905,035

(22) Filed: Sep. 27, 2007

(30) Foreign Application Priority Data
Oct. 13, 2006 (KR) 2006-99724

(51) Int. Cl. H01L 29/788; H01L 21/336

(52) U.S. Cl. 257/315; 438/257; 257/E21.409; 257/E29.3

(57) ABSTRACT

Example embodiments relate to a semiconductor memory device including a channel layer pattern on a substrate, the channel layer pattern having a sidewall and an upper face, a spacer on the sidewall of the channel layer pattern, and a gate electrode covering the sidewall of the channel layer pattern, the spacer and the upper face of the channel layer pattern.

### BACKGROUND OF THE INVENTION

1. Field of the Invention

Example embodiments relate to a semiconductor memory device and a method of manufacturing the same. More particularly, example embodiments relate to a semiconductor memory device including a channel layer pattern, and a method of manufacturing the same.

2. Description of the Related Art

Generally, materials may be classified as a single crystalline material, a poly crystalline material or an amorphous material depending on a structure of the crystal. The single crystalline material may have a single crystalline structure. The poly crystalline material may have a plurality of crystalline structures. The amorphous material may have an irregular molecular arrangement, rather than a crystalline molecular arrangement.

Further, because the poly crystalline material may have a plurality of crystalline structures, the poly crystalline material may include numerous grain boundaries. As a result, the numerous grain boundaries in the poly crystalline material may obstruct movement and control of carriers, e.g., free electrons, holes, etc., so that the poly crystalline material may not possess good electrical characteristics.

The single crystalline material may have only a single crystalline structure, which may not possess any grain boundaries. Therefore, the movement and the control of the carriers in the single crystalline material may not be obstructed by the grain boundaries as compared to those in the poly crystalline material, e.g., the single crystalline material may have electrical characteristics better than those of the poly crystalline material.

As a result, the single crystalline material may be used for a channel layer pattern of a stacked-type semiconductor device having a multi-layered structure. An example of the single crystalline material used for the channel layer pattern may be single crystalline silicon.

In a conventional channel layer pattern of a semiconductor device, impurities may not be uniformly implanted into a surface of a channel layer pattern during an ion implantation process. As a result, the channel layer pattern may have a non-uniform current distribution.

Further, a recess may be formed at a surface portion of the semiconductor substrate to partially expose a bottom face of the channel layer pattern while forming the channel layer pattern. Because the recess may be filled with a gate electrode, the conventional semiconductor memory device may reduce the electrical characteristics.

Further, the channel layer patterns may be formed using a mold layer pattern. The mold layer pattern may include an opening that may define a region of the semiconductor substrate. However, it may be very difficult to provide the channel layer patterns having substantially the same height, particularly when the sides of the channel layer pattern may have a negative profile. Accordingly, when the channel layer patterns have different heights, channels defined by the channel layer patterns in forming a triple gate, for example, may produce different lengths.

### SUMMARY OF THE INVENTION

Example embodiments are therefore directed to a semiconductor memory device and method thereof, which substantially overcome one or more of the problems due to the limitations and disadvantages of the related art.

It is therefore a feature of an example embodiment to provide a semiconductor memory device having a uniform current intensity by forming a spacer on a channel layer pattern.

At least one of the above and other features of example embodiments may be to provide a semiconductor memory device including a channel layer pattern on a substrate, the channel layer pattern having a sidewall and an upper face, a spacer on the sidewall of the channel layer pattern, and a gate electrode covering the sidewall of the channel layer pattern, the spacer and the upper face of the channel layer pattern.

The sidewall of the channel layer pattern may have a generally positive slope.

The channel layer pattern may be doped with impurities.

The spacer may include at least one of a silicon oxide and a silicon nitride.

The semiconductor device may further include a gate insulation layer pattern on the channel layer pattern.

The channel layer pattern may include a single crystalline pattern. The substrate may be a single crystalline substrate.

The semiconductor memory device may further include an insulation layer pattern on the substrate, the insulation layer pattern having an opening partially exposing the substrate, and a plug formed in the opening. The channel layer pattern may be on the insulation layer pattern and on the plug.

The semiconductor memory device may further include a gate insulation layer pattern on the channel layer pattern.

At least one of the above and other features of example embodiments may be to provide a semiconductor memory device including a channel layer pattern having the channel layer pattern having a sidewall and an upper face, a gate electrode covering the sidewall and the upper face of the channel layer pattern, and an ion channel on the channel layer pattern, the ion channel having a length shorter than that of an interface between the channel layer pattern and the gage electrode.

The length of the ion channel may vary in accordance with a height of a spacer on the channel layer pattern. The height of the spacer may be substantially equal to or less than a height of the channel layer pattern.

At least one of the above and other features of example embodiments may also be to provide a method of manufacturing a semiconductor memory device. The method may include forming a channel layer pattern on a substrate, the channel layer pattern having a sidewall and an upper face, forming a spacer on the sidewall of the channel layer pattern, and forming a gate electrode to cover the sidewall of the channel layer pattern, the spacer and the upper face of the channel layer pattern.

Forming the channel layer pattern may include forming an amorphous layer on the substrate, converting a crystalline structure of the amorphous layer into a single crystalline structure, and patterning the single crystalline layer. A sidewall of the channel layer pattern may have a generally positive slope.

The method may further include implanting impurities into the channel layer pattern.

Forming the spacer may include forming an insulation layer on the insulation layer pattern having the channel layer pattern, and etching the insulation layer.

The method may further include forming a gate insulation layer pattern on the upper face of the channel layer pattern. The substrate may be prepared as a single crystalline substrate.

The method may further forming an insulation layer pattern on the substrate, the insulation layer pattern having an opening partially exposing the substrate, filling the opening with a plug, forming the channel layer pattern on the insulation layer and on the plug, and forming a gate insulation layer pattern on the channel layer pattern having the spacer. The channel layer pattern may be single crystalline.

The plug and the channel layer pattern may be formed separately or simultaneously with each other.

Forming the channel layer pattern may include forming a mold layer pattern on the insulation layer pattern, the mold layer pattern having an opening exposing the plug and defining a region for the channel layer pattern, filling the opening of the mold layer pattern with a single crystalline layer by a selective epitaxial growth process using the plug as a seed layer, removing the single crystalline layer until an upper face of the mold layer pattern is exposed to form the channel layer pattern, and removing the mold layer pattern.

Forming the channel layer pattern may include forming an amorphous layer on the insulation layer pattern having the plug, emitting a light to the amorphous layer to convert a crystalline structure of the amorphous layer into a single crystalline structure, and patterning the single crystalline layer

### BRIEF DESCRIPTION OF THE DRAWINGS

The above and other features and advantages of the example embodiments will become more apparent to those of ordinary skill in the art by describing in detail example embodiments thereof with reference to the attached drawings, in which:

FIG. 1 illustrates a perspective view of a semiconductor memory device having a channel layer pattern in accordance with an example embodiment;

FIG. 2 illustrates a cross-sectional view taken along a line I-I′ in FIG. 1;

FIGS. 3 to 5 illustrate perspective views of a method of manufacturing the semiconductor memory device in FIG. 1; and

FIGS. 6 to 12 illustrate perspective views of a method of manufacturing a stacked-type semiconductor memory device in accordance with another example embodiment.

### DESCRIPTION OF EXAMPLE EMBODIMENTS

Korean Patent Application No. 2006-99724 filed on Oct. 13, 2006, in the Korean Intellectual Property Office, and entitled: “Semiconductor Memory Device and Method of Manufacturing the Same,” is incorporated by reference herein in its entirety.

Example embodiments will now be described more fully hereinafter with reference to the accompanying drawings. The invention may, however, be embodied in different forms and should not be construed as limited to the embodiments set forth herein. Rather, these example embodiments are provided so that this disclosure will be thorough and complete, and will fully convey the scope of the invention to those skilled in the art.

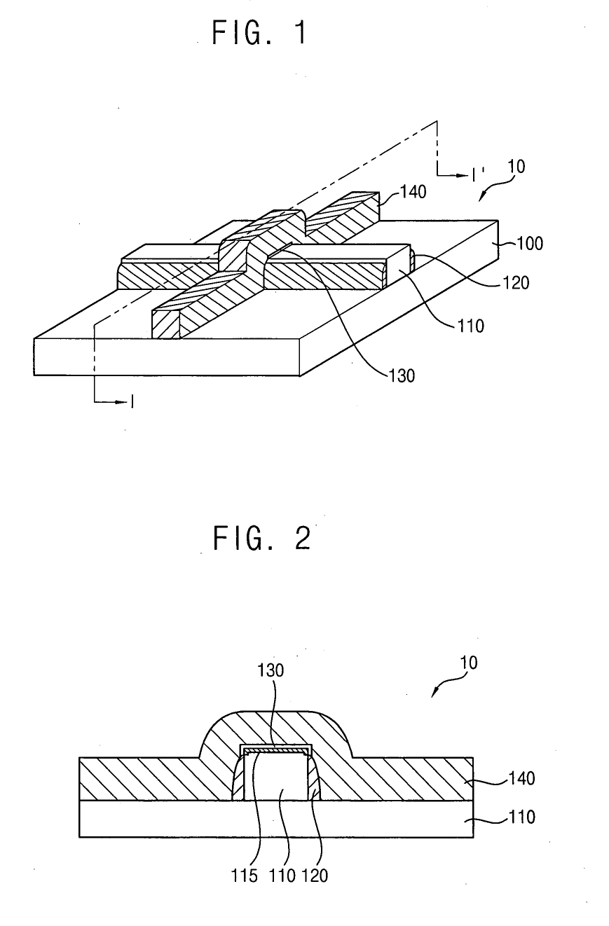

FIG. 1 illustrates a perspective view of a semiconductor memory device having a channel layer pattern in accordance with an example embodiment, and FIG. 2 illustrates a cross-sectional view taken along a line I-I′ in FIG. 1.

Referring to FIGS. 1 and 2, a semiconductor memory device 10 may include a semiconductor substrate 100. The semiconductor substrate 100 may include a channel layer pattern 110, a spacer 120, a gate insulation layer pattern 130 and a gate electrode 140 formed on the semiconductor substrate 100.

The semiconductor substrate 100 may be a single crystalline substrate. Examples of the single crystalline substrate may be at least one of a silicon substrate, a germanium substrate, a silicon-germanium substrate, a silicon-on-insulator (SOI) substrate, and a substrate having a thin layer that may be formed by an epitaxial process. It should be appreciated that other materials may be employed.

The channel layer pattern 110 may include a single crystalline pattern formed on the semiconductor substrate 100. The channel layer pattern 110 may be generally a pin shape having a sidewall and an upper face. It should be appreciated that the channel layer pattern 110 may be formed in other shapes. Further, the channel layer pattern 110 may be obtained by a selective epitaxial growth (SEG) process, for example, using the semiconductor substrate 100 as a seed layer. Alternatively, the channel layer pattern 110 may be obtained by forming an amorphous layer on the semiconductor substrate 100, and by emitting a laser beam to the amorphous layer so as to crystallize the amorphous layer. Further, the channel layer pattern 110 may be obtained by a bonding process on a single crystalline layer.

Further, the sidewall of the channel layer pattern 110 may have a positive (or upward) slope, i.e., the channel layer pattern 110 may be generally a trapezoid shape having an upper side and a lower side, in which the lower side is greater than the upper side. Alternatively, the sidewall of the channel layer pattern 110 may have a negative (or downward) slope, i.e., the channel layer pattern 110 may be generally a trapezoid shape having an upper side and a lower side, in which the lower side is shorter than the upper side. Even further, the sidewall of the channel layer pattern 110 may have generally a vertical slope, i.e., perpendicular to the substrate 100, such that the channel layer pattern 110 has a cross-section that may have a generally rectangular shape. It should be appreciated that other shapes of the channel layer pattern 110 may be utilized.

Furthermore, the channel layer pattern 110 may include an ion channel 115 formed by doping impurities into the channel layer pattern 115. Examples of the impurities may be at least one of boron, arsenic and phosphorous. It should be appreciated that other impurities may be employed to dope the channel layer pattern 110. In an example embodiment, the impurities may be formed in the channel layer pattern 110 simultaneously with the formation of the channel layer pattern 110. Alternatively, the impurities may be subsequently formed in the channel layer pattern 110 by an additional ion implantation process.

In this example embodiment, the ion channel 115 may be formed from the channel layer pattern 110 including the impurities that has a conductive type opposite to that of the gate electrode 140. The ion channel 115 may have a length shorter than that of an interface between the channel layer pattern 110 and the gate electrode 140. That is, the length of the ion channel 115 may be shorter than a summed length of both sidewalls and an upper face in the channel layer pattern 110. For example, the length of the ion channel 115 may vary in accordance with a height of the spacer 120 on the channel layer pattern 110. Further, the height of the spacer 120 may be substantially equal to or less than the height of the channel layer pattern 110.

The spacer 120 may be formed on the sidewall of the channel layer pattern 110. The spacer 120 may be formed by at least one of a silicon oxide layer and a silicon nitride layer. It should be appreciated that other materials may be employed to form the spacer 120.

When the channel layer patterns 110 have different heights, the spacer 120 may function to reduce and/or prevent lengths of channels from being different from each other. Because the spacer 120 may be formed on the sidewall of the channel layer pattern 110, the channel may be formed only on the upper face of the channel layer pattern 110, even though the gate electrode 140 may cover both sidewalls and the upper face of the channel layer pattern 110. That is, the spacer 120 may be arranged between the gate electrode 140 and the channel layer pattern 110, which may prevent the sidewalls with the channel layer pattern 110 from being part of the length of the channel. Further, as mentioned above, the length of the ion channel 115 may vary in accordance with the height of the spacer 120 on the channel layer pattern 110. Thus, the ion channel 115 may be provided with a desirable length by controlling the height of the spacer 120 on the sidewall of the channel layer pattern 110. As a result, the channels in the channel layer pattern 110 may have substantially the same length.

Further, when the impurities are implanted into the channel layer pattern 110 having the positive side face, the spacer 120 may function to reduce and/or prevent a retained dose of the impurities from being non-uniformly distributed in the channel layer pattern 110, e.g., because the spacer 120 may be formed on the positive sidewall of the channel layer pattern 110, the spacer 120 may reduce and/or prevent the impurities from being implanted into the positive sidewall during the ion implantation process.

Furthermore, the spacer 120 may cover a recess (not shown) to reduce and/or prevent the recess from being filled with a conductive material of the gate electrode 140. The recess may be formed at a surface of the semiconductor substrate 100 during the formation of the channel layer pattern 110 by using a laser, for example. That is, the spacer 120 may reduce and/or prevent a non-uniform current distribution caused when filling the recess with the gate electrode 140. Further, residue of conductive material that may remain in the recess after forming the gate electrode (and may connect the gate electrode with an adjacent gate electrode) may be reduced and/or prevented.

In case when the sidewall of the channel layer pattern 110 may have a downward slope, the spacer 120 may reduce and/or prevent conductive residues from remaining along the sidewall of the channel layer pattern 110 during the formation of the gate electrode 140.

The gate insulation layer pattern 130 may be formed between the channel layer pattern 110 and the gate electrode 140. The gate insulation layer pattern 130 may include, for example, but not limited to, a silicon oxide layer. The silicon oxide layer may be formed by depositing silicon oxide on the channel layer pattern 110 by a low pressure chemical vapor deposition (LPCVD) process. Alternatively, the silicon oxide layer may be formed by wet-oxidizing a surface of the channel layer pattern 110. Further, the silicon oxide layer may be formed by thermally oxidizing the surface of the channel layer pattern 110 under an oxidation atmosphere including oxygen being applied to the channel layer pattern 110. It should be appreciated that other methods may be employed to form the silicon oxide layer.

In an implementation, the gate insulation layer pattern 130 may include a metal oxide layer including metal oxide. Examples of the metal oxide may be HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, V₂O₃, La₂O₃, Pr₂O₃, Sb₂O₃, Sb₂O₅, CaO, etc. The above metal oxide may be used alone or in a combination thereof.

The gate electrode 140 may extend along a direction substantially perpendicular to a lengthwise direction of the channel layer pattern 110. Further, the gate electrode 140 may be formed on the channel layer pattern 110 having the spacer 120 and the semiconductor substrate 100. In an example embodiment, the gate electrode 140 may be formed to cover the side face of the channel layer pattern 110, on which the spacer 120 may be formed, and may cover the upper face of the channel layer pattern 110.

Further, the gate electrode 140 may include a conductive material. The conductive material may be at least one of a doped polysilicon, and a metal. More particularly, the gate electrode 140 may include a polysilicon layer doped with n-type impurities, a polysilicon layer/metal silicide layer, and/or a metal layer. It should be appreciated that other materials may be employed to form the gate electrode 140.

Hereinafter, a method of manufacturing the semiconductor memory device 10 having the channel layer pattern 110, on which the spacer 120 may be formed, is described in detail.

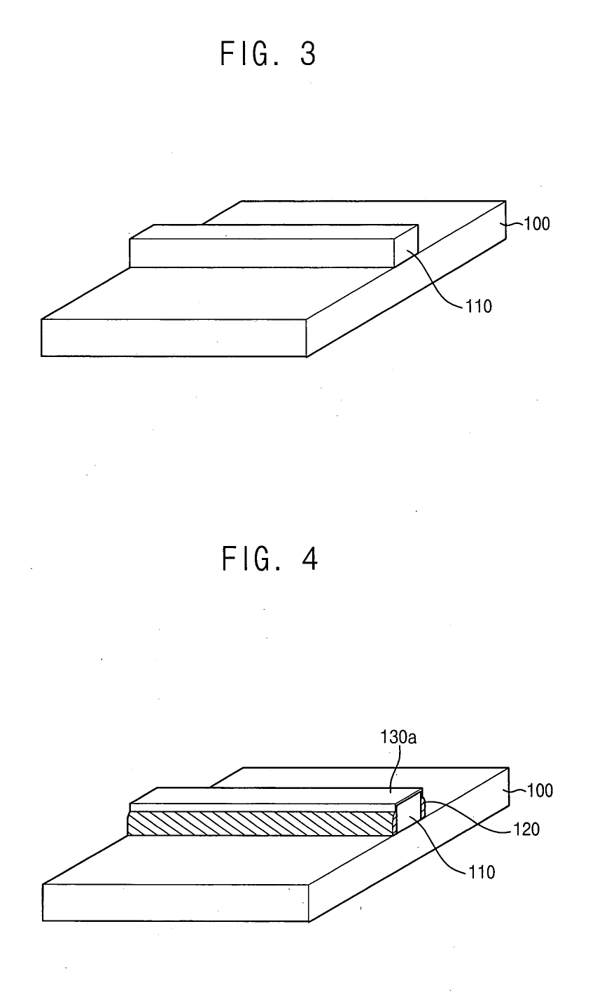

FIGS. 3 to 5 illustrate perspective views of a method of manufacturing the semiconductor memory device 10 in FIG. 1.

Referring to FIG. 3, the single crystalline substrate 100 may be prepared. Examples of the single crystalline substrate 100 may be a silicon substrate, a germanium substrate, a silicon-germanium substrate, a SOI substrate, and a substrate having a thin layer that may be formed by an epitaxial process, etc. In an example embodiment, the silicon substrate may be used as the single crystalline substrate 100.

The channel layer pattern 110 may then be formed on the single crystalline substrate 100. The channel layer pattern 110 may have generally a shape of a pin having a side face and an upper face. It should be appreciated that other shapes may be employed.

The channel layer pattern 110 may be formed by forming an amorphous layer on the substrate 100, and by emitting light, e.g., a laser beam, to the amorphous layer to crystallize the amorphous layer. In particular, when the laser beam is emitted to the amorphous layer to form the amorphous layer on the substrate 100, the emission of the laser beam may cause a phase change of the amorphous layer. The phase change caused by the emission of the laser beam may change the amorphous layer into a liquid state. Therefore, the single crystalline structure of the single crystalline substrate 100 may serve as a seed layer to the liquid amorphous layer, thereby converting the crystalline structure of the amorphous layer into the single crystalline structure. Further, because the amorphous layer may undergo a phase change and crystallize in a short period, e.g., several nano seconds, the liquid amorphous layer may not flow from the single crystalline substrate 100 even though the phase of the amorphous layer may be changed into a liquid state.

Because the phase of the amorphous layer may be changed into the liquid state using the laser beam, the emission of the laser beam may be carried out at a temperature high enough to melt the amorphous layer. Thus, when the amorphous layer includes the silicon layer having a melting point of about 1,410° C., the laser beam may emit at a temperature of greater than about 1,410° C. Further, an apparatus for emitting the laser beam may be an excimer laser, for example. Further, to rapidly emit the laser beam for a short period of time, the laser beam may have a structure capable of scanning. Moreover, the single crystalline substrate 100 may be heated while emitting the laser beam. The heating of the single crystalline substrate 100 may reduce a temperature gradient in the amorphous layer when the phase of the amorphous layer is changed by emitting the laser beam. In an example embodiment, when the laser beam is emitted to the amorphous layer, the single crystalline substrate 100 may be heated to a temperature of about 400° C. The emission of the laser beam may change the crystalline structure of the amorphous layer into the single crystalline structure.

The single crystalline layer may then be patterned to form the channel layer pattern 110. In an example embodiment, the channel layer pattern 110 may include the side face having a generally vertical profile or a generally positive profile. When the channel layer pattern 110 is formed, the substrate 100 making contact with a bottom face of the channel layer pattern 110 may be etched, which may form a recess (not shown). If the recess is filled with the gate electrode 140, the semiconductor memory device 10 may have a non-uniform current distribution.

Referring to FIG. 4, the spacer 120 may be formed on the side face of the channel layer pattern 110.

In an example embodiment, an insulation layer (not shown) may be formed on the substrate 100 having the channel layer pattern 110. The insulation layer may include, for example, but not limited to, a silicon oxide layer and a silicon nitride layer. Further, the insulation layer may have a thickness of about 100 Å to about 700 Å. The insulation layer may be etched until an upper face of the channel layer pattern 110 is exposed to form the spacer 120 on the side face of the channel layer pattern 110.

When the channel layer patterns 110 have different heights, the spacer 120 may reduce and/or prevent the lengths of the channels from being different from each other. Further, when the channel layer pattern 110 has generally a trapezoid shape, the spacer 120 may function to reduce and/or prevent a retained dose of the impurities from being non-uniformly distributed in the channel layer pattern 110, which may be caused by implanting the impurities into the side face of the channel layer pattern 110. Further, the length of the ion channel 115 may vary in accordance with a height of the spacer 120 on the channel layer pattern 110. Further, the height of the spacer 120 may be substantially equal to or less than the height of the channel layer pattern 110.

Furthermore, the spacer 120 may cover the recess, which may be formed at a surface of the semiconductor substrate 100 when forming the channel layer pattern 110, to reduce and/or prevent the recess from being filled with the conductive material of the gate electrode 140.

The channel layer pattern 110 having the spacer 120 may be doped with the impurities. The impurities may be at least one of boron, phosphorous and arsenic. It should be appreciated that other impurities may be employed. The impurities may be used alone or in combination. Further, the impurities may be formed in the channel layer pattern 110 by a diffusion process or an ion implantation process. It should also be appreciated that other process may be employed to form impurities in the channel layer pattern 110.

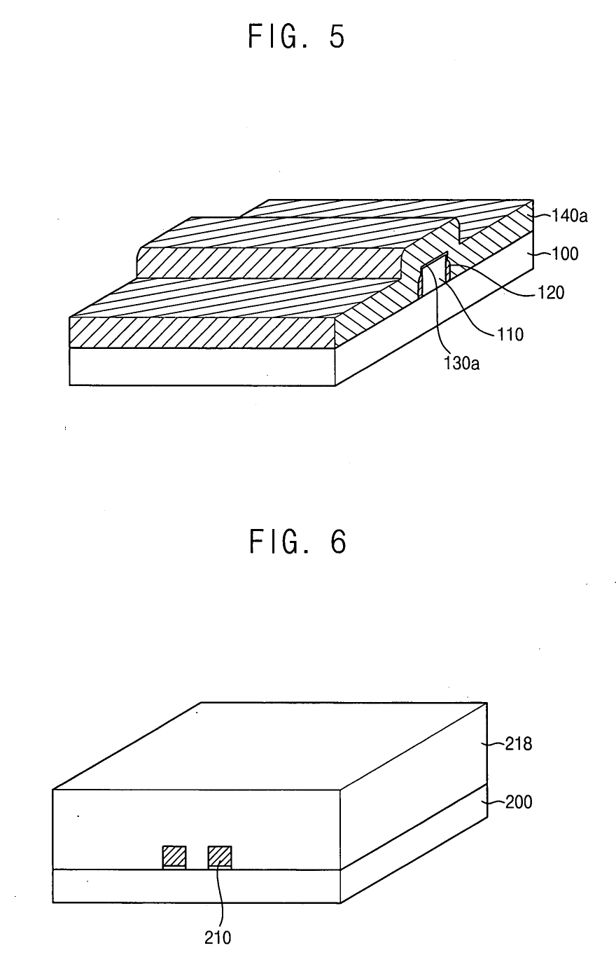

Referring to FIG. 5, a gate insulation layer 130a may be formed on the resultant structure, e.g., the channel layer pattern 110. The gate insulation layer 130a may include a silicon oxide layer. It should be appreciated that the gate insulation layer 130a may contain other materials.

The silicon oxide layer may be formed by depositing silicon oxide on the channel layer pattern 110 by a low pressure chemical vapor deposition (LPCVD) process. Alternatively, the silicon oxide layer may be formed by wet-oxidizing a surface of the channel layer pattern 110. Further, the silicon oxide layer may be formed by thermally oxidizing the surface of the channel layer pattern 110 under an oxidation atmosphere including oxygen being applied to the channel layer pattern 110. It should be appreciated that other methods may be employed to form the silicon oxide layer.

In an implementation, the gate insulation layer 130a may include a metal oxide layer including a metal oxide. Examples of the metal oxide may include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, V₂O₃, La₂O₃, Pr₂O₃, Sb₂O₃, Sb₂O₅, CaO, etc. These can be used alone or in a combination thereof.

Further, although not illustrated in FIG. 5, the gate insulation layer 130a may be formed on the spacer 120 and/or the substrate 100.

A conductive material may be deposited on the substrate 100 having the gate insulation layer 130a to form a conductive layer 140a. Examples of the conductive material may include at least one of a doped polysilicon and a metal. More particularly, the conductive layer 140a may include at least one of a polysilicon layer doped with n-type impurities, a polysilicon layer/metal silicide layer and a metal layer. The metal silicide layer may be at least one of a tungsten silicide layer, a titanium silicide layer, a cobalt silicide layer and a tantalum silicide layer; and the metal layer may include at least one of a tungsten layer and a titanium layer. It should be appreciated that other materials may be employed to form the conductive layer 140a.

A mask pattern (not shown) may be formed at a region where the gate electrode 140 may be formed (as shown in FIG. 1). In an example embodiment, the mask pattern may have generally a linear shape extending along a direction substantially perpendicular to the lengthwise direction of the channel layer pattern 110. It should be appreciated that other shapes of the mask pattern may be employed. The conductive layer 140a and the gate insulation layer 130a may then be etched using the mask pattern as an etching mask to form the gate electrode 140 and the gate insulation layer pattern 130.

Further, the gate electrode 140 may be formed on the channel layer pattern 110 having the spacer 120 and the substrate 100. In an example embodiment, the gate electrode 140 may have generally a linear shape for covering the side face of the channel layer pattern 110, on which the spacer 120 may be formed, and may cover the upper face of the channel layer pattern 110.

FIGS. 6 to 12 illustrate perspective views of a method of manufacturing a stacked-type semiconductor memory device in accordance with another example embodiment.

Referring to FIG. 6, a single crystalline substrate 200 may be prepared. Examples of the single crystalline substrate 200 may include at least one of a silicon substrate, a germanium substrate, a silicon-germanium substrate, an SOI substrate, a substrate having a thin layer that may be formed by an epitaxial process. It should be appreciated that other materials may be employed to form the substrate 200. In an example embodiment, the silicon substrate may be used as the single crystalline substrate 200. Further, a semiconductor structure 210 such as, but not limited to, a first gate electrode, a metal wiring, a logic device, etc., may be formed on the substrate 200. Further, an insulation interlayer 218 may be formed on the substrate 200.

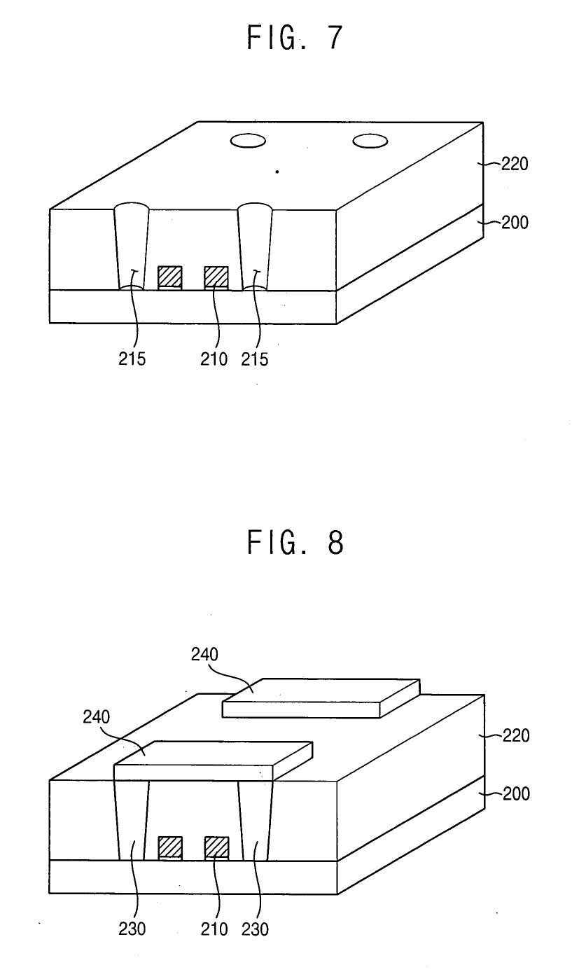

Referring to FIG. 7, the insulation interlayer 218 may be patterned by an etching process to form an insulation layer pattern 220 having an opening 215 that exposes an upper face of the substrate 200.

After the formation of the insulation layer pattern 220, the exposed upper face of the substrate 200 through the opening 215 may be additionally treated using a hydrofluoride solution, for example. The surface treatment of the substrate 200 may remove a thin native oxide layer on the upper face of the substrate 200, and may also form a hydrogen passivation layer on the upper face of the substrate 200.

Referring to FIG. 8, the opening 215 may be filled with a plug 230. The plug 230 may include a single crystalline contact. In an example embodiment, the plug 230 may be formed by an SEG process using the upper face of the substrate 200 through the opening 215 as a seed layer. It should be appreciated that other processes may be employed to form the plug.

A channel layer pattern 240 may then be formed on the insulation layer pattern 220. The channel layer pattern 240 may be connected to the plug 230. Further, the plug 230 and the channel layer pattern 240 may be formed in-situ or simultaneously with each other.

The channel layer pattern 240 may be formed by forming an amorphous layer on the substrate 200, and by emitting a laser beam to the amorphous layer to crystallize the amorphous layer. Accordingly, processes for forming the single crystalline structure may be substantially the same as those illustrated with reference to FIG. 3. Thus, any further illustrations with respect to the processes are omitted herein for brevity.

The single crystalline layer may be patterned using an etching mask to form a channel layer pattern 240 including a side face that has a positive slope e.g., the channel layer pattern 240 may have generally a trapezoid shape having an upper length and a lower length greater than the upper length.

Alternatively, the channel layer pattern 240 may be formed by an SEG process using the plug 230 as a seed layer.

Further, a mold layer pattern (not shown) may be formed on the insulation layer pattern 220. The mold layer pattern may have an opening (not shown) for exposing the plug 230 and for defining a region where the channel layer pattern 240 may be formed. The SEG process may be carried out using the plug 230 as the seed layer to form a single crystalline layer in the opening 215 of the mold layer pattern. In an example embodiment, the SEG process may be performed using a source gas at a temperature of about 800° C. to about 900° C. Examples of the source gas may include at least one of SiCl₄, SiH₄, SiH₂Cl₂, and SiHCl₃. It should be appreciated that other source gases may be employed. The gases may be used alone or in a combination thereof. The single crystalline layer may be planarized to expose an upper face of the mold layer pattern. The mold layer pattern may then be removed to form the channel layer pattern 240 including a side face that has a downward slope, e.g., the channel layer pattern 240 may have generally a trapezoid shape having an upper side and a lower side, in which the lower side is shorter than the upper side.

Alternatively, the channel layer pattern 240 may be formed by a bonding process on a single crystalline layer.

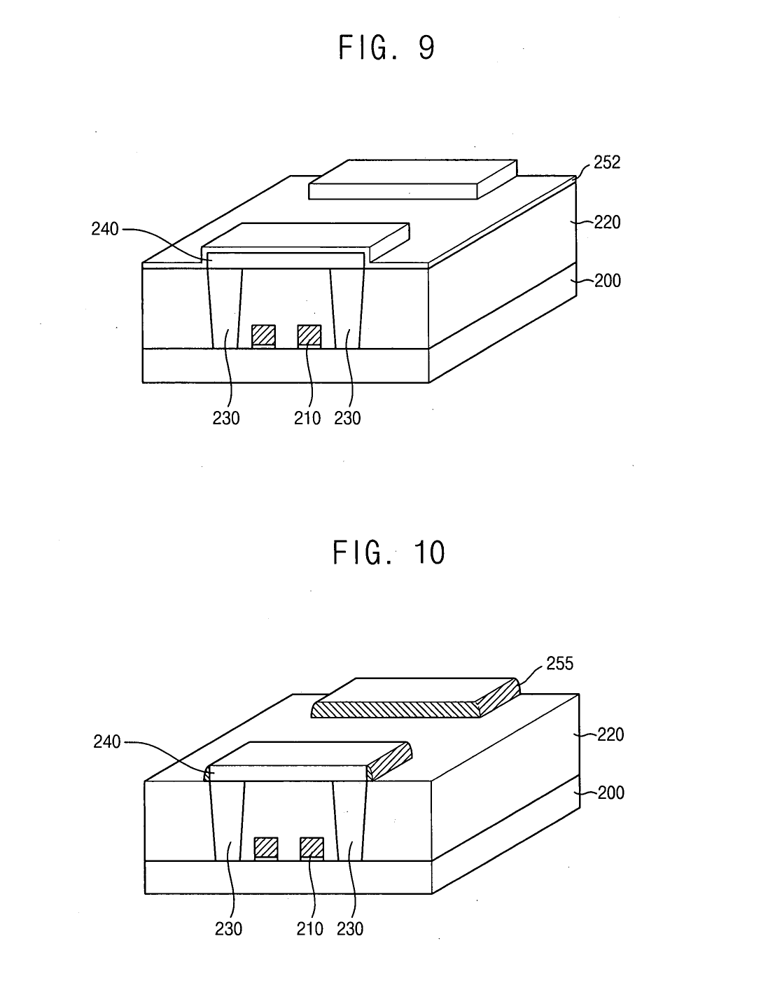

Referring to FIG. 9, an insulation layer 252 for a spacer 255 (shown in FIG. 10) may be formed on the insulation layer pattern 220 having the channel layer pattern 240. The insulation layer 252 for the spacer 255 may include at least one of a silicon oxide layer and a silicon nitride layer. It should be appreciated that other materials may be employed to form the insulation layer 252. Further, the insulation layer 252 for the spacer 255 may have a thickness of about 100 Å to about 700 Å, preferably about 200 Å to about 400 Å.

Referring to FIG. 10, the insulation layer 252 may be etched to form the spacer 255 on the side face of the channel layer pattern 240.

When the channel layer patterns 240 have different heights, the spacer 255 may reduce and/or prevent lengths of channels from being different from each other. Further, when the channel layer pattern 240 having the positive side face is doped with impurities, the spacer 255 may reduce and/or prevent a retained dose of the impurities from being non-uniformly distributed in the channel layer pattern 240, which may be caused by implanting the impurities into the side face of the channel layer pattern 240. Furthermore, the spacer 255 may cover the recess, which may be generated at a surface of the semiconductor substrate 200 while forming the channel layer pattern 240, to reduce and/or prevent the recess from being filled with a conductive material of a gate electrode.

The channel layer pattern 240 having the spacer 255 may be doped with the impurities. Examples of the impurities may include at least one of boron, phosphorous and arsenic. It should be appreciated that other impurities may be employed. The impurities may be used alone or in combination. Further, the impurities may be formed in the channel layer pattern 240 by at least one of a diffusion process and an ion implantation process. It should be appreciated that other methods may be employed.

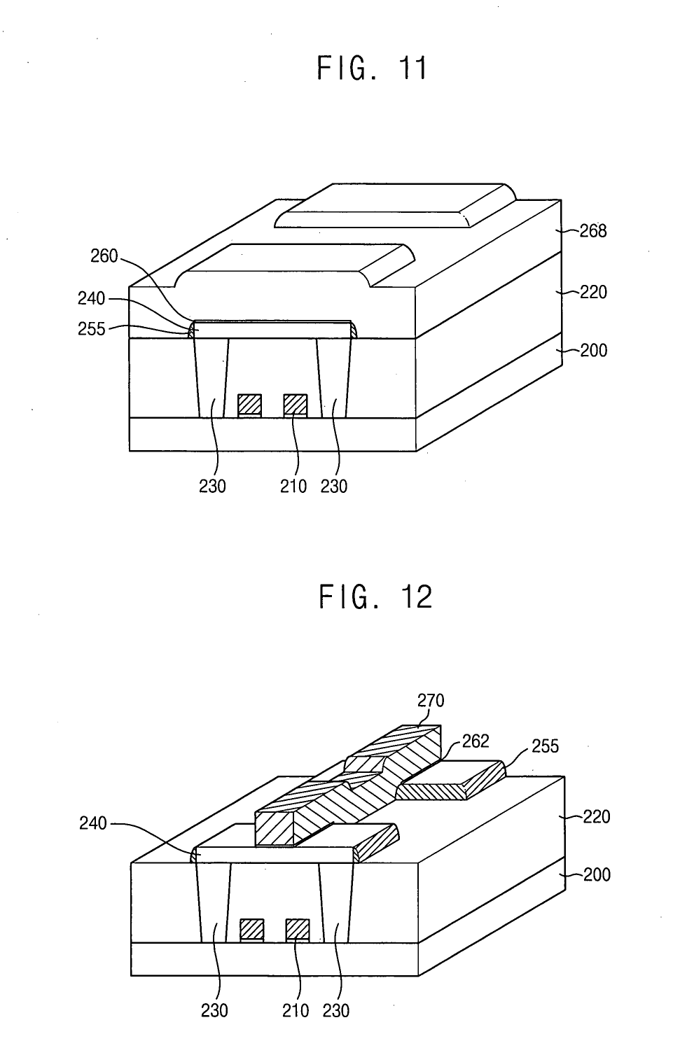

Referring to FIG. 11, a gate insulation layer 260 may be formed on the resultant structure. The gate insulation layer 260 may include a silicon oxide layer, for example.

The silicon oxide layer may be formed by depositing silicon oxide on the channel layer pattern 240 by a low pressure chemical vapor deposition (LPCVD) process. Alternatively, the silicon oxide layer may be formed by wet-oxidizing a surface of the channel layer pattern 240. Further, the silicon oxide layer may be formed by thermally oxidizing the surface of the channel layer pattern 240 under an oxidation atmosphere including oxygen being applied to the channel layer pattern 240. It should be appreciated that other methods may be employed to form silicon oxide layer.

In an implementation, the gate insulation layer 260 may include a metal oxide layer including metal oxide. Examples of the metal oxide may include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, V₂O₃, La₂O₃, Pr₂O₃, Sb₂O₃, Sb₂O₅, CaO, etc. The metal oxide may be used alone or in a combination thereof.

A conductive material may be deposited on the substrate 200 having the gate insulation layer 260 to form a conductive layer 268. The conductive material may be at least one of a doped polysilicon and a metal. It should be appreciated that other materials may be employed to form the conductive material. The gate electrode 140 may include at least one of a polysilicon layer doped with n-type impurities, a polysilicon layer/metal silicide layer and a metal layer. Examples of the metal silicide layer may include at least one of a tungsten silicide layer, a titanium silicide layer, a cobalt silicide layer, a tantalum silicide layer; and examples of the metal layer may include at least one of a tungsten layer, a titanium layer.

Referring to FIG. 12, a mask pattern (not shown) may be formed on the conductive layer 268 at a region where the gate electrode may be formed. In an example embodiment, the mask pattern may have generally a linear shape extending along a direction substantially perpendicular to the lengthwise direction of the channel layer pattern 240.

The conductive layer 268 and the gate insulation layer 260 may then be etched using the mask pattern as an etching mask to form the gate electrode 270 and the gate insulation layer pattern 262.

In an example embodiment, the gate electrode 270 may extend on the direction substantially perpendicular to the lengthwise direction of the channel layer pattern 240. Further, the gate electrode 270 may be formed on the channel layer pattern 240 having the spacer 255. The gate electrode 270 may have generally a linear shape covering the sidewalls of the channel layer pattern 240, on which the spacer 255 may be formed, and covering the upper face of the channel layer pattern 240. Further, a silicon nitride layer (not shown) may be then formed on the insulation layer pattern 262 having the gate electrode 270. The silicon nitride layer may be anisotropically etched to form a gate spacer on a sidewall of the gate electrode 270. Impurities may be implanted into the channel layer pattern 240 using the gate spacer and the gate electrode 270 as an ion implantation mask. The channel layer pattern 240 may be thermally treated to form a contact region, which may correspond to source/drain regions (not shown), in the channel layer pattern 240.

In example embodiments, a method of manufacturing a semiconductor memory device having a channel layer pattern and a spacer may be applied to a stacked-type memory device. Alternatively, the method of manufacturing the semiconductor memory device may be applied to other semiconductor memory devices, e.g., a DRAM, an SRAM, an MRAM, etc., as well as the stacked-type memory device.

In example embodiments, the spacer may be formed on the sidewalls of the channel layer pattern. Therefore, non-uniformity of a retained dose of the impurities formed when the channel layer pattern has a positive slope may be suppressed. Further, when the channel layer patterns have different heights, channels formed in the channel layer patterns may be provided to have substantially the same length because the ion channel may have the controllable length. Furthermore, a recess formed at a surface portion of the substrate to partially expose a bottom face of the channel layer pattern when the channel layer pattern is formed using a laser, for example, may not be buried with the gate electrode.

Moreover, when the channel layer pattern has a downward slope, a polysilicon layer may not remain on the sidewall of the channel layer pattern when the polysilicon layer is etched to form the gate electrode. Therefore, the semiconductor memory device may have a uniform current distribution.

In the figures, the dimensions of layers and regions may be exaggerated for clarity of illustration. It will also be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Further, it will be understood that when a layer is referred to as being “under” or “above” another layer, it can be directly under or directly above, and one or more intervening layers may also be present. In addition, it will also be understood that when a layer is referred to as being “between” two layers, it can be the only layer between the two layers, or one or more intervening layers may also be present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature relationship to another element(s) or feature(s) as illustrated in the figures. It will be understood that the spatially relative terms are intended to encompass different orientations of the device in use or operation in addition to the orientation depicted in the figures. For example, if the device in the figures is turned over (or upside down), elements or layers described as “below” or “beneath” other elements or layers would then be oriented “above” the other elements or layers. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor memory device, comprising:
a channel layer pattern on a substrate, the channel layer pattern having a sidewall and an upper face;
a spacer on the sidewall of the channel layer pattern; and
a gate electrode covering the sidewall of the channel layer pattern, the spacer and the upper face of the channel layer pattern.

2. The semiconductor memory device as claimed in claim 1, wherein the sidewall of the channel layer pattern has a generally positive slope.

3. The semiconductor memory device as claimed in claim 1, wherein the channel layer pattern is doped with impurities.

4. The semiconductor memory device as claimed in claim 1, wherein the spacer comprises at least one of a silicon oxide and a silicon nitride.

5. The semiconductor memory device as claimed in claim 1, further comprising a gate insulation layer pattern on the channel layer pattern.

6. The semiconductor memory device as claimed in claim 5, wherein the channel layer pattern includes a single crystalline pattern.

7. The semiconductor memory device as claimed in claim 1, wherein the substrate is a single crystalline substrate.

8. The semiconductor memory device as claimed in claim 7, further comprising:
an insulation layer pattern on the substrate, the insulation layer pattern having an opening partially exposing the substrate; and
a plug in the opening,
wherein the channel layer pattern is on the insulation layer pattern and on the plug.

9. The semiconductor memory device as claimed in claim 8, further comprising a gate insulation layer pattern on the channel layer pattern.

10. A method of manufacturing a semiconductor memory device, comprising:
forming a channel layer pattern on a substrate, the channel layer pattern having a sidewall and an upper face;
forming a spacer on the sidewall of the channel layer pattern; and
forming a gate electrode to cover the sidewall of the channel layer pattern, the spacer and the upper face of the channel layer pattern.

11. The method as claimed in claim 10, wherein forming the channel layer pattern comprises:
forming an amorphous layer on the substrate;
converting a crystalline structure of the amorphous layer into a single crystalline structure; and
patterning the single crystalline layer.

12. The method as claimed in claim 11, wherein the sidewall of the channel layer pattern has a generally positive slope.

13. The method as claimed in claim 10, after forming the channel layer pattern, further comprising implanting impurities into the channel layer pattern.

14. The method as claimed in claim 10, wherein forming the spacer comprises:
forming an insulation layer on the insulation layer pattern having the channel layer pattern; and
etching the insulation layer.

15. The method as claimed in claim 10, further comprising forming a gate insulation layer pattern on the upper face of the channel layer pattern.

16. The method as claimed in claim 10, wherein the substrate is prepared as a single crystalline substrate.

17. The method as claimed in claim 16, further comprising:
forming an insulation layer pattern on the substrate, the insulation layer pattern having an opening partially exposing the substrate;
filling the opening with a plug;
forming the channel layer pattern on the insulation layer pattern and on the plug; and
forming a gate insulation layer pattern on the channel layer pattern having the spacer,
wherein the channel layer pattern is single crystalline.

18. The method as claimed in claim 17, wherein the plug and the channel layer pattern are formed separately or simultaneously with each other.

19. The method as claimed in claim 17, wherein forming the channel layer pattern comprises:
forming a mold layer pattern on the insulation layer pattern, the mold layer pattern having an opening exposing the plug and defining a region for the channel layer pattern;
filling the opening of the mold layer pattern with a single crystalline layer by a selective epitaxial growth process using the plug as a seed layer;
removing the single crystalline layer until an upper face of the mold layer pattern is exposed to form the channel layer pattern; and
removing the mold layer pattern.

20. The method as claimed in claim 17, wherein forming the channel layer pattern comprises:
forming an amorphous layer on the insulation layer pattern having the plug;
emitting a light to the amorphous layer to convert a crystalline structure of the amorphous layer into a single crystalline structure; and
patterning the single crystalline layer.

21. A semiconductor memory device, comprising:
a channel layer pattern on a substrate, the channel layer pattern having a sidewall and an upper face;
a gate electrode covering the sidewall and the upper face of the channel layer pattern; and
an ion channel on the channel layer pattern, the ion channel having a length shorter than that of an interface between the channel layer pattern and the gate electrode.

22. The semiconductor memory device as claimed in claim 21, wherein the sidewall of the channel layer pattern has a generally positive slope.

23. The semiconductor memory device as claimed in claim 21, wherein the length of the ion channel varies in accordance with a height of a spacer on the channel layer pattern.

24. The semiconductor memory device as claimed in claim 23, wherein the height of the spacer is substantially equal to or less than a height of the channel layer pattern.
